(19) United States
(12) Patent Application Publication
(10) Pub. No.: US 2007/0237969 A1
(43) Pub. Date: Oct. 11, 2007

(54) Surface-metallized polyimide material and method for manufacturing the same

(76) Inventors: Wha-tzong Whang, Hsinchu (TW); Yu-sheng Hsiao, Hsinchu (TW)

Correspondence Address: MARTINE PENILLA & GENCARELLA, LLP, 710 LAKEWAY DRIVE, SUITE 200, SUNNYVALE, CA, 94085, US

(21) Appl. No.: 11/637,987

(22) Filed: Dec. 12, 2006

(30) Foreign Application Priority Data
Apr. 7, 2006 (TW) 95112434

(51) Int. Cl. H01L 21/28; B32B 17/06

(52) U.S. Cl. 428/433; 257/664; 29/825; 428/450; 428/434

(57) ABSTRACT

A method for manufacturing a surface-metallized polyimide material includes performing an alkaline treatment on a surface of a polyimide material to cause ring opening of the polyimide material on the surface; the surface of the polyimide material being subject to an ion exchange process for being displaced by a first metal ion exclusive of palladium ion, gold ion, silver ion, and copper ion; and performing a wet reduction process to reduce the first metal ion on the surface of the polyimide material into a first metal that adheres to the surface of the polyimide material. A surface-metallized polyimide material produced according to the aforementioned method is also disclosed.

### BACKGROUND OF THE INVENTION

a) Field of the Invention

The invention relates to a polyimide material and a method for manufacturing the same and, more particularly, to a surface-metallized polyimide material and a method for manufacturing the same.

b) Description of the Related Art

Since the trend in the development of consumer electronic products has been towards being light, thin, miniature, compact, and multifunctional in recent years, traditional rigid printed circuit boards (PCBs) no longer meet the requirements therefor and thus flexible PCBs are developed. Among various materials for forming flexible PCBs, polyimide has been applied increasingly on different flexible PCBs due to its better electrical characteristic, chemical resistance, and heat resistance in addition to its flexibility, the ability to continuous production, light weight, small volume, etc.

In order to form circuit layout on a surface of polyimide material, an electrically conductive metal layer, like a copper layer, must be formed on the surface of polyimide material. Referring to FIG. 1, a conventional surface-metallized polyimide material 1 is obtained by coating a layer of adhesive 12 such as an acrylic group or an epoxy resin group adhesive on the surface of polyimide material 11, and then laminating a copper foil 13 thereon. Since the high temperature resistance, size stability, line density, and reliability of long term operation for the surface-metallized polyimide material 1 cannot meet the requirement, another adhesiveless flexible PCB has been developed.

FIGS. 2A, 2B, and 2C respectively illustrate three types of adhesiveless surface-metallized polyimide materials. FIG. 2A shows a surface-metallized polyimide material 21 formed with coating. First, a layer of polyamic acid 212, which has better adhesiveness and size stability, is coated on the surface of a copper foil 213. Afterward, forming a thin film by attaching the copper foil 213 to a polyimide material 211 and an amidation process thereto. However, the disadvantage of the coating method lies in that the copper foil is apt to be warped or damaged and the process yield is thus reduced since when the copper foil has a thickness less than 10 μm, the stress of the film at the time of curing which is caused by the mechanical tension and the thermal ring closure of polyamic acid is hard to control. Moreover, this method is not suitable for making double-sided electrically conductive flexible PCBs owing to the generation of bubbles during the process.

FIG. 2B shows a surface-metallized polyimide material 22 formed by lamination, wherein the surface-metallized polyimide material 22 is formed by laminating a thermoplastic polyimide material 221 and a copper foil 222 at a high temperature under a high pressure. The disadvantage of this method is that the lamination has to be preformed in vacuum at a high temperature of 350° C. with a high pressure, and this method is not suitable for making a thin copper layer. Moreover, since the thermoplastic polyimide material is not suitable for use in chemical etching process, technologies like laser or plasma etching must be used, which in turn increases the manufacturing cost.

Referring to FIG. 2C, a surface-metallized polyimide material 23 produced by sputtering/electroplating is illustrated, in which a thin copper layer 232 is sputtered on a surface of a polyimide material 231 via a sputtering process in vacuum, so that the surface of the polyimide material 231 is electrically conductive, and then a thick copper layer 233 is deposited by electroplating. Since the electrically conductive copper layer 232 has to be prepared in vacuum for this method, the process cost, time, production, and unsuitability of making double-sided electrically conductive flexible PCB are the problems to be overcome. In addition, the adhesion force between the copper layer and the surface-metallized polyimide material prepared by this method is weak.

Another method for preparing a surface-metallized polyimide material is to form a palladium metal layer on a surface of a polyimide material to render the surface electrical conductivity, and then deposit other metal such as copper, silver, or gold on the surface of the polyimide material by electroplating. However, the disadvantages of this method are that palladium metal is quite expensive and the strict manufacturing condition thereof is unfavorable to the production.

Concluding from the above, our goal is to produce a polyimide material with one or both surfaces metallized without using high-priced metal or operating under the strict manufacturing conditions such as high temperature, high pressure, vacuum, etc. in the process.

### SUMMARY OF THE INVENTION

An object of the invention is to provide a surface-metallized polyimide material and a method for manufacturing the same, wherein it is not necessary to use palladium, gold, silver, or copper metal as a medium layer in the manufacturing process, and the surface-metallized polyimide material can be produced under relatively easily-attained manufacturing conditions.

To achieve the aforementioned object, a method for manufacturing a surface-metallized polyimide material of the invention includes the following steps: performing an alkaline treatment to a surface of a polyimide material by an alkaline solution to cause ring opening of the polyimide material on the surface; the surface of the polyimide material being subject to an ion exchange process for being displaced by a first metal ion exclusive of palladium ion, gold ion, silver ion, and copper ion; and performing a wet reduction process to reduce the first metal ion on the surface of the polyimide material to a first metal that adheres to the surface of the polyimide material.

A surface-metallized polyimide material formed by the aforementioned method includes: a polyimide material; a first metal ion layer formed on a surface of the polyimide material, wherein the first metal ion and —COO⁻ group of the polyimide material surface are bonded as a metal complex, and the first metal ion is exclusive of palladium, gold, silver, and copper ions; and a first metal layer formed via reduction of the first metal ion layer.

According to the surface-metallized polyimide material and the method for manufacturing the same of the invention, metal such as palladium, gold, silver, or copper is unnecessary as a medium layer, and strict manufacturing conditions like high temperature, high pressure, and vacuum are not required during the manufacturing process. Hence, the manufacturing cost of the surface-metallized polyimide material is greatly reduced and polyimide films with both sides surface-metallized can be easily produced.

### BRIEF DESCRIPTION OF THE DRAWINGS

FIG. 1 is the structure of a conventional surface-metallized polyimide material.

FIG. 2A is the structure of a conventional surface-metallized polyimide material formed by coating.

FIG. 2B is the structure of a conventional surface-metallized polyimide material formed by lamination.

FIG. 2C is the structure of a conventional surface-metallized polyimide material formed by sputtering/electroplating.

FIG. 3 is a flow chart illustrating a manufacturing process of surface-metallized polyimide material according to a preferred embodiment of the invention.

FIGS. 4A, 4B, 4C, and 4D are schematic diagrams illustrating the structure of polyimide material during the manufacturing process of a manufacturing method of the invention.

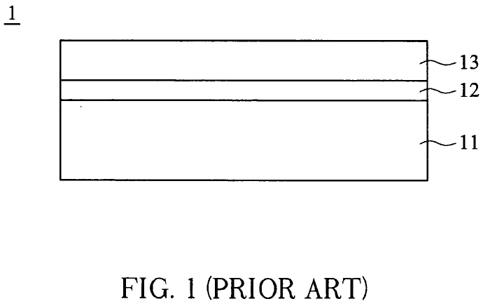

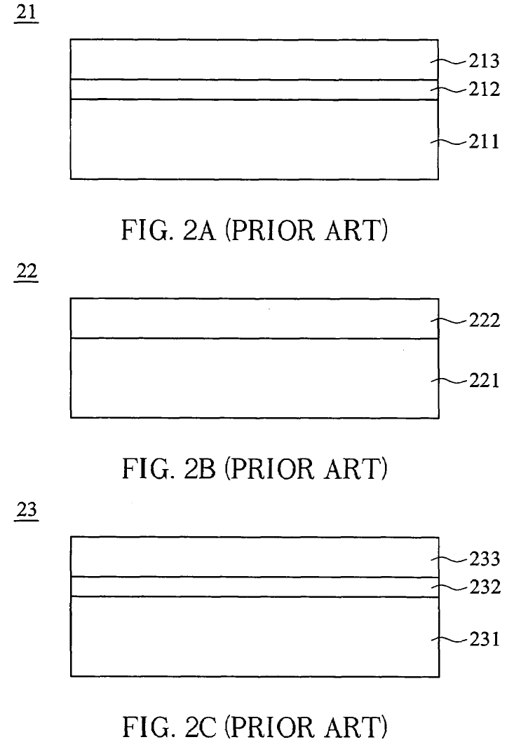

### DETAILED DESCRIPTION OF THE INVENTION

*The preferred embodiments of a surface-metallized polyimide material and a method for manufacturing the same according to the invention will be described in detail, with reference to the drawings in which like reference numerals denote like elements.

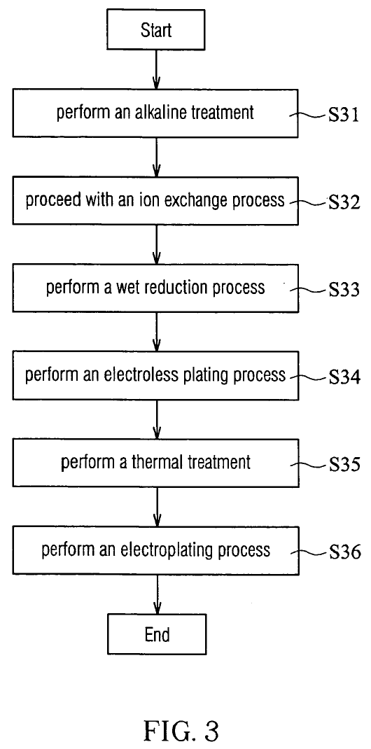

Polyimide is a polymer containing an imide group, and can have different properties by polymerization of the imide group with suitable monomers as required such as aliphatic or aromatic groups. FIG. 3 shows a method for producing a surface-metallized polyimide material according to a preferred embodiment of the invention. First, an alkaline treatment is performed on a surface of a polyimide material by using an alkaline solution so as to result in ring opening of the polyimide material (S31) on the surface. Next, the surface of the polyimide material is subject to an ion exchange process for being displaced by a first metal ion exclusive of palladium ion, gold ion, silver ion, and copper ion (S32). Finally, a wet reduction process is performed to reduce the first metal ion on the surface of the polyimide material into a first metal that adheres to the surface of the polyimide material (S33), thereby a polyimide material with the first metal adhered to its surface is obtained.

For increasing the thickness, uniformity, and flatness of the first metal layer on the surface of the polyimide material, an additional electroless plating process can be performed (S34) to continue the deposition of the first metal on the surface of the polyimide material, thereby the thickness and uniformity thereof are increased.

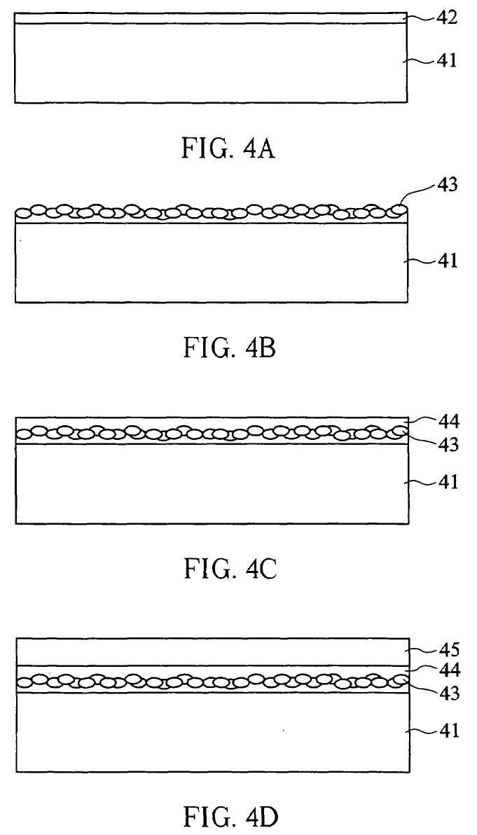

FIGS. 4A, 4B, and 4C illustrate the preparation of polyimide material with nickel metallized-surface as an example. First, an alkaline treatment is performed on a surface of a polyimide material with an alkaline solution like LiOH, KOH, NaOH, Be(OH)₂, Mg(OH)₂, Ca(OH)₂, or organic alkaline. For example, treat the surface of the polyimide material with 1M of KOH solution for 1 to 90 minutes, preferably for 10 to 15 minutes. After the alkaline treatment, as shown in FIG. 4A, —COO⁻ group resulted from the ring opening of the polyimide material 41 on the surface undergoing the alkaline treatment forms a thin layer 42 of metal complex with K⁺ ions. After that, an ion exchange process is treated to the thin layer 42 using a NiSO₄ solution for displacing Ni²⁺ ions onto the thin layer 42. For example, treat the thin layer 42 with 50 mM of NiSO₄ solution for 1 second to 30 minutes, preferably for 5 seconds to 10 minutes. Next, reduce the Ni²⁺ ions in the thin layer 42 with a reducing agent. For example, treat the thin layer 42 with NaBH₄ for 1 second to 60 minutes, preferably for 5 seconds to 40 minutes. Thus, a nickel-catalyzed reduction layer 43 that adheres to the surface of the polyimide material 41, as shown in FIG. 4B, is obtained, wherein the size of the nickel particles is smaller than approximately 100 nm. It is to be noted that the reducing agent such as LiBH₄, dimethylamineborane (DMAB), NaH₂PO₂, or N₂H₄ can also be used for the wet reduction process. If an additional electroless plating process is performed, a nickel metal layer 44 with relatively flat surface is obtained as shown in FIG. 4C, wherein the electroless plating process can be performed by using an electroless electroplating solution prepared with NiSO₄, sodium citrate, lactic acid and DMAB.

It is to be noted that, in the above, on the surface of the polyimide material, a nickel metal layer is formed as an example. However, iron ion, cobalt ion, cadmium ion, indium ion, or tin ion can also be used for the ion exchange process to form the aforementioned metal layer on the surface of the polyimide material.

Referring back to FIG. 3, the polyimide material is electrically conductive after the surface-metallization, and therefore it can undergo an electroplating process (S36) so that a second metal can be deposited on the surface-metallized surface of the polyimide material. As shown in FIG. 4D, the surface of the polyimide material that has been surface-metallized can be subject to an electroplating process to form a second metal layer 45. Metal such as gold, silver, copper, or metal prepared by a reduction process is commonly used as the conductive wire for circuit layout. It is also to be noted that the method of forming the second metal layer 45 is not limited to the electroplating process, while the electroless plating process can be used to deposit metal alloy or metal oxide on the surface-metallized surface of the polyimide material.

Furthermore, the surface of the polyimide material that has been surface-metallized can undergo a thermal treatment (S35) to change the lattice structure of the first metal layer. Taking the polyimide material with a nickel-metallized surface as an example, a thermal treatment is performed thereto at 80° C. to 450° C., preferably at 150° C. to 450° C., for 1 to 90 minutes, thereby a more distinctly distributed lattice structure of Ni(111), which is advantageous to etching of metal wires, can be obtained. In general, the more Ni(111) is distributed, the better the resolution of the etched wire is, providing the possibility of thinning wires. It is to be stressed that the thermal treatment step can be performed after not only forming the first metal layer but also forming the second metal layer.

The method for manufacturing a surface-metallized polyimide material of the invention also provides possibilities of different circuit layouts. For example, after the formation of the nickel metal surface, the nickel metal surface can be coated with a photoresist, and then exposed, developed, and etched to form a specified pattern. Alternatively, the surface of the polyimide material can also be coated with a photoresist and exposed and developed to form a specified pattern, so as to expose the surface of the polyimide material corresponding to the specified pattern, followed by subsequent surface metallization steps such as the alkaline treatment process. The specified pattern can even be formed by directly printing or spraying the alkaline solution onto the polyimide, so as to perform the alkaline treatment to the surface corresponding to the specified pattern, and subsequent steps like the ion exchange process are performed thereafter.

The surface-metallized polyimide material produced according to the aforementioned method includes: a polyimide material; a first metal ion layer formed on a surface of the polyimide material, wherein the first metal ion is bond to the —COO⁻ group of the surface of the polyimide material as a metal complex, and the first metal ion does not include palladium ion, gold ion, silver ion, and copper ion; and a first metal layer formed by reducing the first metal ion layer.

For the surface-metallized polyimide material and the method for manufacturing the same according to the invention, palladium, gold, silver, or copper metal is not used during the process as the medium, while metal of lower cost such as nickel is used instead, and various metal as desired, for example, gold, silver, or copper, can be electroplated thereon subsequently. Moreover, the conditions for the method of the invention are easy to attain. For example, the surface-metallized polyimide material can be manufactured with the wet chemical process at 5° C. to 90° C. Since strict manufacturing conditions like high temperature, high pressure, vacuum, etc. are not required, no only manufacturing cost of the surface-metallized polyimide material is greatly reduced, but the polyimide film with both sides surface-metallized can be easily made. In addition, nickel metal, when used as the medium, has better adhesion than copper to the polyimide material. For example, when a cross-cut test (ASTM D3359-95) with a 3M Scotch 61-PK tape is carried out, no pealing-off is found. Also, the surface of the nickel metal layer is more compact, which can lower the leakage of copper into the polyimide.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method for manufacturing a surface-metallized polyimide material, comprising:
performing an alkaline treatment with an alkaline solution on a surface of a polyimide material to cause ring opening of the polyimide material on the surface;
the surface of the polyimide material being subject to an ion exchange process for being displaced by a first metal ion exclusive of palladium ion, gold ion, silver ion, and copper ion; and
performing a wet reduction process to reduce the first metal ion on the surface of the polyimide material into a first metal that adheres to the surface of the polyimide material.

2. The method for manufacturing a surface-metallized polyimide material as described in claim 1, further comprising:
depositing the first metal on the surface of the polyimide material by an electroless plating process.

3. The method for manufacturing a surface-metallized polyimide material as described in claim 1, further comprising:
coating a photoresist on the surface of the polyimide material, exposing and developing to obtain a specified pattern such that the surface of the polyimide material corresponding to the specified pattern is exposed.

4. The method for manufacturing a surface-metallized polyimide material as described in claim 1, wherein a specified pattern is directly formed on the surface of the polyimide material using the alkaline solution, so that the alkaline treatment is performed for the surface of the polyimide material on which the specified pattern is formed.

5. The method for manufacturing a surface-metallized polyimide material as described in claim 4, wherein the specified pattern is formed by manual or mechanical printing or spraying.

6. The method for manufacturing a surface-metallized polyimide material as described in claim 1, further comprising:
etching a specified pattern on the surface of the polyimide material that has been surface-metallized.

7. The method for manufacturing a surface-metallized polyimide material as described in claim 1, further comprising:
performing a thermal treatment at 80° C. to 450° C. for 1 to 90 minutes.

8. The method for manufacturing a surface-metallized polyimide material as described in claim 1, further comprising:
performing a thermal treatment at 150° C. to 450° C. for 1 to 90 minutes.

9. The method for manufacturing a surface-metallized polyimide material as described in claim 1, wherein the first metal ion is nickel ion.

10. The method for manufacturing a surface-metallized polyimide material as described in claim 1, wherein the first metal ion is iron ion, cobalt ion, cadmium ion, indium ion, or tin ion.

11. The method for manufacturing a surface-metallized polyimide material as described in claim 1, further comprising:
performing an electroplating process to deposit a second metal on the surface of the polyimide material that has been surface-metallized.

12. The method for manufacturing a surface-metallized polyimide material as described in claim 11, wherein the second metal is gold, silver, or copper, or metal prepared via reduction.

13. The method for manufacturing a surface-metallized polyimide material as described in claim 1, further comprising:
performing an electroplating process or an electroless plating process to deposit a metal alloy or a metal oxide on the surface of the polyimide material that has been surface-metallized.

14. The method for manufacturing a surface-metallized polyimide material as described in claim 1, wherein the alkaline solution is LiOH, KOH, NaOH, Be(OH)₂, Mg(OH)₂, Ca(OH)₂, or organic alkaline solution.

15. The method for manufacturing a surface-metallized polyimide material as described in claim 1, wherein the ion exchange process comprises treating with a salt solution containing the first metal ion for 1 second to 30 minutes.

16. The method for manufacturing a surface-metallized polyimide material as described in claim 1, wherein the ion exchange process comprises treating with a salt solution containing the first metal ion for 5 seconds to 10 minutes.

17. The method for manufacturing a surface-metallized polyimide material as described in claim 1, wherein the wet reduction process comprises treating with LiBH₄, NaBH₄, dimethylamineborane, NaH₂PO₂, or N₂H₄ for 1 second to 60 minutes.

18. The method for manufacturing a surface-metallized polyimide material as described in claim 1, wherein the wet reduction process comprises treating with LiBH₄, NaBH₄, dimethylamineborane, NaH₂PO₂, or N₂H₄ for 5 seconds to 40 minutes.

19. The method for manufacturing a surface-metallized polyimide material as described in claim 1, wherein the steps each is performed at a temperature of 5° C. to 90° C.

20. A surface-metallized polyimide material, comprising:
a polyimide material;
a first metal ion layer formed on a surface of the polyimide material, wherein the first metal ion and —COO⁻ group of the polyimide material on the surface are bonded as a metal complex, and the first metal ion is exclusive of palladium ion, gold ion, silver ion, and copper ion; and
a first metal layer formed by reduction of the first metal ion layer.

21. The surface-metallized polyimide material as described in claim 20, wherein the first metal ion is nickel ion.

22. The surface-metallized polyimide material as described in claim 20, wherein the first metal ion is iron ion, cobalt ion, cadmium ion, indium ion, or tin ion.

23. The surface-metallized polyimide material as described in claim 20, further comprising:
a second metal layer formed on the surface of the first metal layer.

24. The surface-metallized polyimide material as described in claim 23, wherein the second metal is gold, silver, copper, or a metal prepared via reduction.
